(19) United States
(12) Patent Application Publication
(10) Pub. No.: US 2007/0238027 A1
(43) Pub. Date: Oct. 11, 2007

(54) METHOD FOR GENERATING ALIGNMENT MARKS AND RELATED MASKS THEREOF

(76) Inventor: Han-Tung Hsu, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/278,957

(22) Filed: Apr. 6, 2006

(51) Int. Cl. G03F 1/00; G03F 9/00; G03C 5/00

(52) U.S. Cl. 430/5; 430/311; 430/22

(57) ABSTRACT

A method for generating alignment marks on a substrate is disclosed. The method includes: providing a mask, the mask includes at least one alignment mark set, wherein the alignment mark set includes a first alignment mark capable of being utilized in a first exposure machine and a second alignment mark capable of being utilized in a second exposure machine; and utilizing the mask to generate the first alignment mark and the second alignment mark on the substrate in the first exposure machine; wherein the first alignment mark is adjacent to the second alignment mark.

### BACKGROUND OF THE INVENTION

1. Field of the Invention

The present invention relates to a method for generating alignment marks and related mask thereof, and more particularly, to a method for generating alignment marks capable of being utilized in different exposure machines and related mask thereof.

2. Description of the Prior Art

In the semiconductor manufacturing field, a photolithography method is commonly used for manufacturing a semiconductor device. In the photolithography method, a photoresist is formed on a semiconductor wafer. The photoresist is exposed by using a photomask and then developed for forming a circuit pattern. Next, a layer, which is located under the photoresist, can be etched such that a needed circuit pattern can be formed. In order to produce an electronic device, a plurality of the above-mentioned processes should be performed. Taking the liquid crystal display (LCD) for example, five photolithography processes must be performed through five masks such that circuit patterns of the gate electrode (GE) layer, semiconductor (SE) layer, source/drain (SD) layer, contact hole (CH) layer, and pixel electrode (PE) layer can be formed.

As known by those skilled in the art, in the exposing step, the photomask must be correctly aligned with the semiconductor substrate. Alignment marks, which are formed in the photomask and in the wafer, are used for the alignment. That is, before performing the photolithography process, the mask must first be well aligned with the substrate so that the circuit pattern can be correctly imaged on the substrate. The alignment mark, as it is called, is utilized to support the aforementioned alignment operation of the mask and the substrate. In general, the gate electrode layer (first layer) mask not only comprises the circuit pattern corresponding to the electronic device, but also comprises pre-defined alignment marks. Therefore, during the gate electrode layer exposure operation, the alignment marks are formed on the substrate through the gate electrode layer mask. In addition, the following masks (such as the above-mentioned semiconductor layer, source/drain layer, contact hole layer, and pixel electrode layermasks) also comprise predetermined alignment marks. Therefore, before exposure operations are performed on the semiconductor layer, source/drain layer, contact hole layer, and pixel electrode layer, the alignment marks of the semiconductor layer, source/drain layer, contact hole layer, and pixel electrode layer masks are utilized to align the alignment marks, previously formed on the substrate. This can ensure the accuracy of the exposure operations.

However, the positions where the alignment marks are formed directly influences the results of the entire semiconductor manufacturing process. Please refer to FIG. 1, which illustrates the corresponding relationships between positions of exposed circuit patterns and positions of the alignment marks. First, please note that the exposure operation of the gate electrode layer (the first layer) cannot be performed perfectly. That is, the exposure of the gate electrode layer changes its shape (as the curve 100 shown in FIG. 1).

We assume that the alignment marks defined by the gate electrode layer mask are exposed on the predetermined positions 110 shown in FIG. 1. As mentioned previously, the first layer is not exposed perfectly. Therefore, the alignment marks are formed more narrowly than the predetermined positions 110. When the following exposure operations of the following layers are being performed, the alignment marks of the masks are wider than the alignment marks of the substrate, This makes the exposed circuit pattern also narrower (as the dotted line 150 shown in FIG. 1).

On the other hand, we assume that the alignment marks of the gate electrode layer mask are exposed on the predetermined positions 120. However, the alignment marks are formed more widely than the predetermined positions 120 because of the changing shape. Therefore, when the following exposure operations of the following layers are being performed, the alignment marks of the masks are narrower than the alignment marks of the substrate. This makes the exposed circuit pattern (as the dotted line 160 shown in FIG. 1) become wider, too.

As is disclosed, different positions of the alignment marks causes the difference (as the difference D shown in FIG. 1) between circuit patterns. Generally speaking, the photolithography operations of the five masks are performed by the same exposure machine. Therefore, the five masks utilize the same alignment marks to perform the exposure operations; the exposed circuit pattern has few errors.

Unfortunately, LCD manufacturer may utilize two different exposure machines to produce the LCDs because of manufacturing efficiencies. For example, the LCD manufacturer can use one exposure machine (ex: Canon exposure machine) to perform the exposure operations of multiple masks, and use another exposure machine (ex: Nikon exposure machine) to perform the exposure operations of the other masks.

Please refer to FIG. 2, which is a diagram of a gate electrode layer mask according to the prior art. The alignment marks of two exposure machines are different because of different specifications. Moreover, the positions of the alignment marks of different exposure machines are also different. Therefore, when the gate electrode layer mask is being exposed, the alignment marks corresponding to different exposure machines are imaged on different positions of the glass substrate. As mentioned previously, when two exposure machines are simultaneously utilized to produce the LCD, the previous masks are utilized to perform the exposure operations according to the first alignment mark 210, and the other masks are utilized to perform the exposure operations according to the second alignment mark 220. Because the positions of the first alignment mark 210 and the second alignment mark 220 are not the same, this causes errors of exposed circuit patterns. In other words, the circuit patterns exposed by different masks may have different overlap situations.

### SUMMARY OF THE INVENTION

It is therefore one of the primary objectives of the claimed invention to provide a method for generating alignment marks capable of being utilized in two different exposure machines and related mask thereof, to solve the above-mentioned problem of the prior art.

According to an exemplary embodiment of the claimed invention, a method for generating alignment marks on a substrate is disclosed. The method comprises: providing a mask, where the mask defines at least one alignment mark set, and the alignment mark set comprises a first alignment mark capable of being utilized in a first exposure machine and a second alignment mark capable of being utilized in a second exposure machine; and utilizing the mask to generate the first alignment mark and the second alignment mark on the substrate in the first exposure machine; wherein the first alignment mark is substantially adjacent to the second alignment mark.

According to an exemplary embodiment of the claimed invention, a mask capable of generating alignment marks on a substrate is disclosed. The mask comprises: at least one alignment mark set, where each alignment mark set comprises: a first alignment mark capable of being utilized in a first exposure machine; and a second alignment mark capable of being utilized in a second exposure machine; wherein the first alignment mark is substantially adjacent to the second alignment mark.

The claimed invention alignment mark set comprises adjacent alignment marks, which respectively corresponds to different exposure machines. Therefore, when the LCD is being produced, the overlap situations can be reduced because the distance between alignment marks are reduced. In other words, the claimed invention can decrease the errors of circuit patterns to raise the yield, and makes it more possible to simultaneously utilize two exposure machines to produce the LCD.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the corresponding relationships between positions of exposed circuit patterns and positions of the alignment marks.

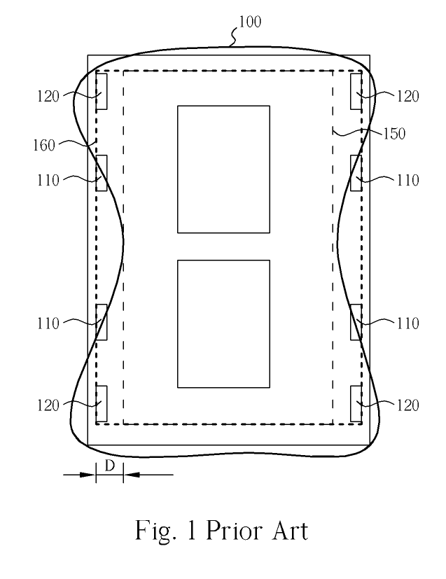

FIG. 2 is a diagram of a gate electrode layer mask according to the prior art.

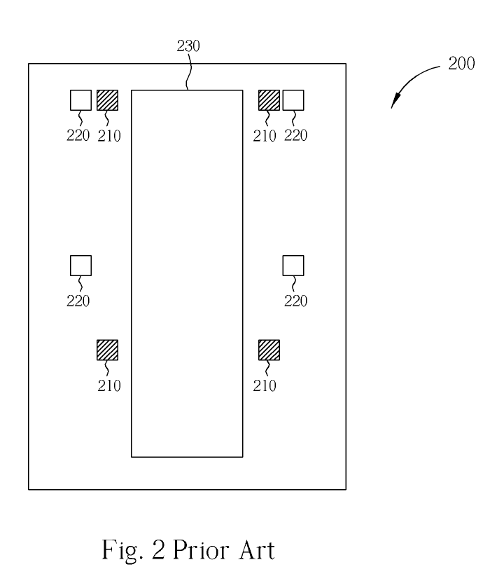

FIG. 3 is a diagram of the gate electrode layer mask according to the present invention.

FIG. 4 is a blow-up diagram of a part of the alignment mark set shown in FIG. 3.

### DETAILED DESCRIPTION

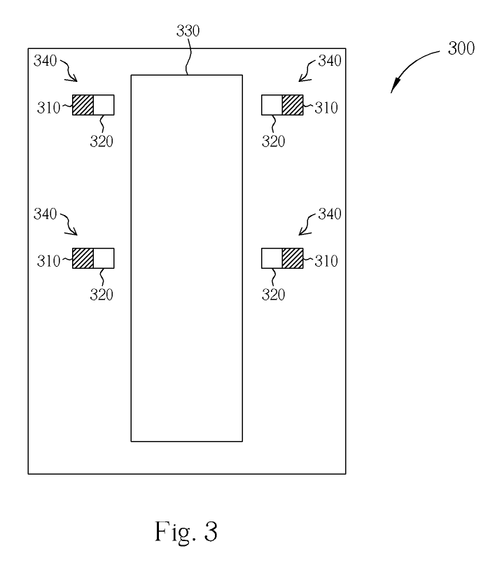

In the following disclosure, we still utilize the LCD as an embodiment of the present invention. Please refer to FIG. 3, which is a diagram of the gate electrode layer mask 300 according to the present invention. As shown in FIG. 3, the present invention gate electrode layer mask 300 comprises a circuit pattern 330 of the LCD and a plurality of alignment mark sets 340, where each alignment mark set 340 also comprises a first alignment mark 310 and a second alignment mark 320. The first alignment mark 310 is utilized for the Canon exposure machine, and the second alignment mark 320 is utilized for the Nikon exposure machine. Please note, in each alignment mark set 340, the first alignment mark 310 is substantially adjacent to the second alignment mark 320.

Because the first alignment mark 310 is substantially adjacent to the second alignment mark 320, when the gate electrode layer mask 300 is utilized to perform the exposure operation, the first alignment mark 310 and the second alignment mark 320 are formed adjacent on the glass substrate. As mentioned previously, the position difference between the first alignment mark 310 and the second alignment mark 320 causes the different overlap situations of the circuit pattern. For example, the present invention can minimize the positional difference between the first alignment mark 310 and the second alignment mark 320 because two alignment marks 310 and 320 are adjacent. Therefore, when the other masks are utilized to perform the exposure operations, because the first alignment mark 310 and the second alignment mark 320 almost correspond to the same location on the glass substrate, the exposed circuit patterns do not have so many errors. Therefore, the present invention can efficiently reduce the error of the overlap situation of the circuit patterns.

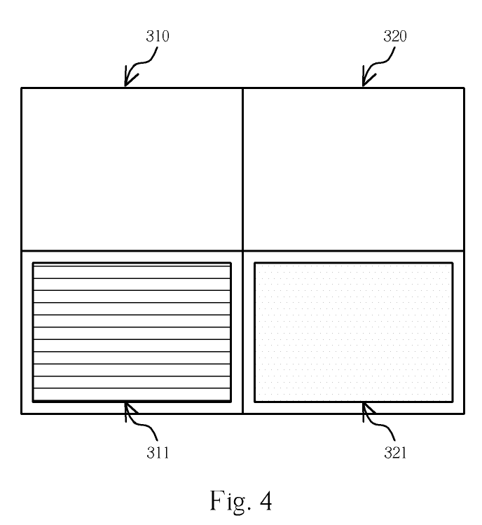

Please refer to FIG. 4, which is a blow-up diagram of a part of the alignment mark set 340 shown in FIG. 3. In general, when the alignment operation is being performed, islands or windows of the alignment marks are aligned. Therefore, as shown in FIG. 4, in the present invention alignment mark set 340, the island 311 of the first alignment mark 310 is adjacent to the island 321 of the second alignment mark 320. Such arrangement can minimize the distance between the second alignment mark 320 and the first alignment mark 310. Furthermore, because the island 321 and the island 311 310 do not overlap, they do not influence the following exposure operations of the other masks. Please note, the present invention does not limit the arrangement of the two alignment marks. For example, if windows are utilized to align each other instead of islands, the present invention can also arrange two windows of the alignment marks to be adjacent. This also obeys the spirit of the present invention.

In the above disclosure, the LCD is only utilized as an embodiment, not a limitation of the present invention. That is, the present invention does not limit the application fields. The present invention method can be utilized to simultaneously use two different exposure machines to manufacture all kinds of electronic products. Therefore, the glass substrate is also utilized as an embodiment here. The present invention can be implemented in a wafer; this also obeys the spirit of the present invention.

Furthermore, the present invention can be utilized in different exposure machines such that they can cooperate to produce a needed electronic device. This also obeys the spirit of the present invention.

In contrast to the prior art, the present invention alignment mark set comprises adjacent alignment marks, which respectively corresponds to different exposure machines. Therefore, when the LCD is being produced, the overlap situations can be reduced because the distance between alignment marks are reduced. In other words, the present invention can decrease the errors of circuit patterns to raise the yield, and makes it more possible to simultaneously utilize two exposure machines to produce the LCD.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for generating alignment marks on a substrate, the method comprising:
providing a mask, the mask defining at least one alignment mark set, the alignment mark set comprising a first alignment mark capable of being utilized in a first exposure machine and a second alignment mark capable of being utilized in a second exposure machine; and
utilizing the mask to generate the first alignment mark and the second alignment mark on the substrate in the first exposure machine;
wherein the first alignment mark is adjacent to the second alignment mark.

2. The method of claim 1, wherein the mask defines a plurality of alignment mark sets, and the first alignment mark is adjacent to the second alignment mark for each alignment mark set.

3. The method of claim 1, wherein the substrate is a glass substrate.

4. The method of claim 3, wherein the glass substrate is utilized in a liquid crystal display (LCD).

5. The method of claim 1, wherein the first exposure machine is a Canon exposure machine and the first alignment mark is utilized in the Canon exposure machine.

6. The method of claim 1, wherein the second exposure machine is a Nikon exposure machine and the second alignment mark is utilized in the Nikon exposure machine.

7. A mask capable of generating alignment marks on a substrate, the mask comprising:
at least one alignment mark set, the alignment mark set comprising:
a first alignment mark capable of being utilized in a first exposure machine; and
a second alignment mark capable of being utilized in a second exposure machine;
wherein the first alignment mark is adjacent to the second alignment mark.

8. The mask of claim 7, wherein the mask comprises a plurality of alignment mark sets, and the first alignment mark is adjacent to the second alignment mark for each alignment mark set.

9. The mask of claim 7, wherein the substrate is a glass substrate.

10. The mask of claim 9, wherein the glass substrate is utilized in a liquid crystal display (LCD).

11. The mask of claim 7, wherein the first exposure machine is a Canon exposure machine and the first alignment mark is utilized in the Canon exposure machine.

12. The method of claim 7, wherein the second exposure machine is a Nikon exposure machine and the second alignment mark is utilized in the Nikon exposure machine.
